(19) United States
(12) Patent Application Publication
(10) Pub. No.: US 2010/0327341 A1
(43) Pub. Date: Dec. 30, 2010

(54) NONVOLATILE SEMICONDUCTOR MEMORY DEVICE HAVING CHARGE STORAGE LAYERS AND MANUFACTURING METHOD THEREOF

(76) Inventor: Atsuhiro SUZUKI, Yokohama-shi (JP)

Correspondence Address: OBLON, SPIVAK, MCCLELLAND MAIER & NEUSTADT, L.L.P., 1940 DUKE STREET, ALEXANDRIA, VA, 22314, US

(21) Appl. No.: 12/618,035

(22) Filed: Nov. 13, 2009

(30) Foreign Application Priority Data
Jun. 25, 2009 (JP) 2009-151248

(51) Int. Cl. H01L 27/112; H01L 21/8246

(52) U.S. Cl. 257/326; 438/587; 438/591; 257/E21.679; 257/E27.102

(57) ABSTRACT

A nonvolatile semiconductor memory device includes first electrodes, a second and a third electrode, a first film, a first inter layer film, a second inter layer film, and a second film. The first electrodes each have a charge storage and a control electrode. The second and the third electrodes are formed above the semiconductor substrate. The first film is formed on each sidewall of the second and third electrodes and formed on the surface of the semiconductor substrate. The first inter layer film filled in a gap between the second and third electrodes. The second inter layer film filled in a gap between the first and second electrode. The second film is formed on the first to third gate electrodes, the first film and the first inter layer film, and a second inter layer insulating film to suppress diffusion of hydrogen atoms included in the first inter layer film.

### CROSS-REFERENCE TO RELATED APPLICATIONS

This application is based upon and claims the benefit of priority from prior Japanese Patent Application No. 2009-151248, filed Jun. 25, 2009, the entire contents of which are incorporated herein by reference.

### BACKGROUND OF THE INVENTION

1. Field of the Invention

This invention relates to a nonvolatile semiconductor memory device having charge storage layers and a manufacturing method thereof.

2. Description of the Related Art

In a nonvolatile semiconductor memory device represented by a flash memory, it is indispensable to improve the quality thereof. The flash memory has memory cells that are formed as FG cells or MONOS cells. It is described in a pamphlet of International Publication No. 2004/023559 that each cell has a charge storage layer and control gate. Whether the characteristic of the cell is good or not is determined according to the charge holding characteristic of the charge storage layer used as one standard.

### BRIEF SUMMARY OF THE INVENTION

A nonvolatile semiconductor memory device according to an aspect of the invention includes:

first gate electrodes each having a charge storage layer formed above a semiconductor substrate with a tunnel insulating film interposed therebetween and a control gate electrode formed above the charge storage layer with an inter gate insulating film interposed therebetween;

a second gate electrode and a third gate electrode formed above the semiconductor substrate with a gate insulating film interposed therebetween, the second and the third gate electrodes are located oppositely in a gate length direction;

a first insulating film formed on each sidewall of the second and the third gate electrodes and formed on the surface of the semiconductor substrate in a region between the second gate electrodes and the third gate electrodes;

a first inter layer insulating film filled in a gap between the second gate electrodes and the third gate electrodes;

a second inter layer insulating film filled in a gap between the first gate electrode which is adjacent to the second gate electrode and the second gate electrode, and gaps between the first gate electrodes; and

a second insulating film formed on the first gate electrodes, the second gate electrode, the third gate electrode, the first insulating film, the first inter layer insulating film, and the second inter layer insulating film to suppress diffusion of hydrogen atoms included in the first inter layer insulating film.

A manufacturing method of a nonvolatile semiconductor memory device according to an aspect of the invention includes:

forming a first gate electrode having a charge storage layer, a inter gate insulating film and a control gate electrode sequentially formed above a semiconductor substrate with a tunnel insulating film interposed there between;

forming a second gate electrode and a third gate electrode above the semiconductor substrate with a gate insulating film interposed therebetween, the second and the third gate electrodes are located oppositely in a gate length direction;

filling a first inter layer insulating film in a gap between the first gate electrode and the second gate electrode;

forming a first insulating film along the surface of the semiconductor substrate and on sidewalls of the second gate electrode and the third gate electrode;

filling a second inter layer insulating film in a gap between the second gate electrode and third gate electrode; and

forming a second insulating film on the first gate electrode, the second gate electrode, the third gate electrode, the first insulating film, the first inter layer insulating film and second inter layer insulating film to suppress diffusion of hydrogen atoms included in the second inter layer insulating film.

### BRIEF DESCRIPTION OF THE SEVERAL VIEWS OF THE DRAWING

FIG. 1 is a block diagram showing a NAND flash memory according to one embodiment of this invention;

FIG. 2 is a cross-sectional view showing the memory of FIG. 1 in a bit line direction; and

FIGS. 3 to 8 are cross-sectional views showing manufacturing steps of the NAND flash memory according to the embodiment of this invention.

### DETAILED DESCRIPTION OF THE INVENTION

An embodiment of this invention will be described with reference to the accompanying drawings. In this explanation, common reference symbols are attached to common portions throughout the drawings.

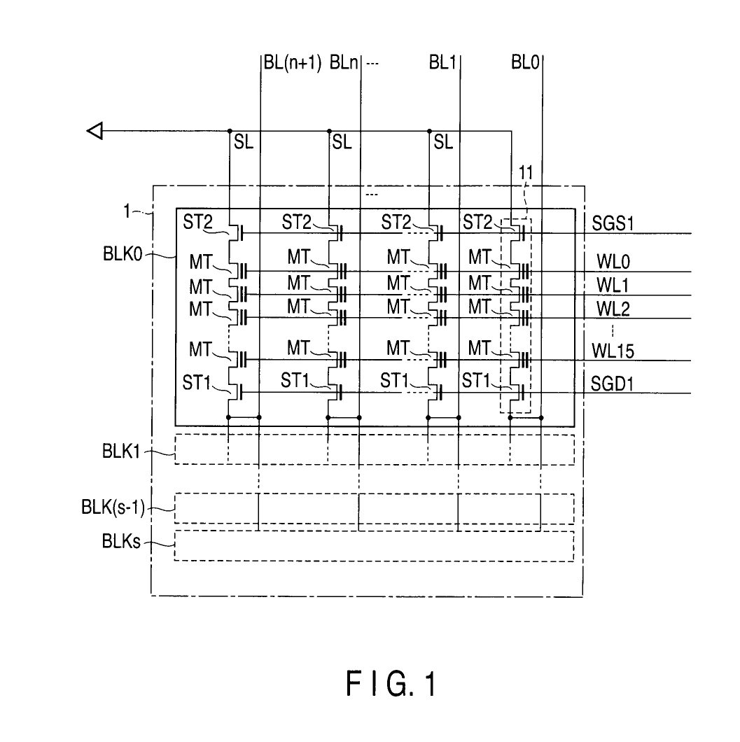

A nonvolatile semiconductor memory device according to one embodiment of this invention and a manufacturing method thereof are explained with reference to FIG. 1. As one example of the nonvolatile semiconductor memory device, a NAND flash memory is explained. As shown in FIG. 1, for example, the NAND flash memory is a semiconductor memory having nonvolatile memory cell transistors MT capable of holding two- or multi-value data. The NAND flash memory has a memory cell array 1.

<Memory Cell Array 1>

As shown in FIG. 1, the memory cell array 1 has a plurality of nonvolatile memory cell transistors MT capable of holding data. For example, each of the nonvolatile memory cell transistors MT is an n-channel MOS transistor having a stacked gate that includes a charge storage layer and control gate. The control gate of each memory cell transistor MT functions as a word line WL, the drain thereof is electrically connected to a bit line BL and the source thereof is electrically connected to a source line SL. Further, the memory cell array 1 has blocks BLK0 to BLKs (s is a natural number) each including plural ones of the nonvolatile memory cell transistors MT.

As shown in FIG. 1, each of the blocks BLK0 to BLKs includes a plurality of NAND strings 11 each of which has series-connected nonvolatile memory cell transistors MT. For example, each of the NAND strings 11 has 16 memory cell transistors MT and select transistors ST1, ST2. The memory cell transistor MT has an FG structure having a charge storage layer (for example, polysilicon layer) formed above a semiconductor substrate with a gate insulating film interposed therebetween and a control gate formed above the charge storage layer with an inter layer insulating film interposed therebetween. The memory cell transistor MT may be formed with a MONOS structure. In this case, the memory cell transistor MT has a charge storage layer (for example, insulating film) formed above a semiconductor substrate with a gate insulating film (tunnel insulating film) interposed therebetween, an insulating film (that is hereinafter referred to as a block layer) formed on the charge storage layer and having a dielectric constant higher than the charge storage layer and a control gate formed on the block layer. In this embodiment, the nonvolatile semiconductor device formed with the FG structure is explained below. The number of memory cell transistors MT is not limited to 16 and may be set to 32, 64 or 128 and is not limited to a specified value. Adjacent two of the memory cell transistors MT commonly use the source or drain. Further, the memory cell transistors MT are arranged to have the current paths thereof series-connected between the select transistors ST1 and ST2. The drain region on one side of the series-connected memory cell transistors MT is connected to the source region of select transistor ST1 and the source region on the other side thereof is connected to the drain region of select transistor ST2.

The control gate electrodes of the memory cell transistors MT that are arranged on the same row are commonly connected to a corresponding one of word lines WL0 to WL15. The gate electrodes of the select transistors ST1, ST2 of the memory cell transistors MT that are arranged on the same row are commonly connected to select gate lines SGD1, SGS1, respectively. For simplifying the explanation, if the word lines WL0 to WL15 are not distinguished, the word line may be simply referred to as a word line WL in some cases. Further, the drains of select transistors ST1 that are arranged on the same column in the memory cell array 1 are commonly connected to a corresponding one of bit lines BL0 to BLn. Further, if the bit lines BL0 to BLn are not distinguished, the bit line may be simply referred to as a bit line BL (n: natural number). The sources of select transistors ST2 are commonly connected to a source line SL.

Further, data is simultaneously written to the plural memory cell transistors MT connected to the same word line WL and the unit is called a page. In addition, data items in the plural NAND strings 11 are simultaneously erased in the block BLK unit.

<Cross-Sectional View of Memory Cell Array 1>

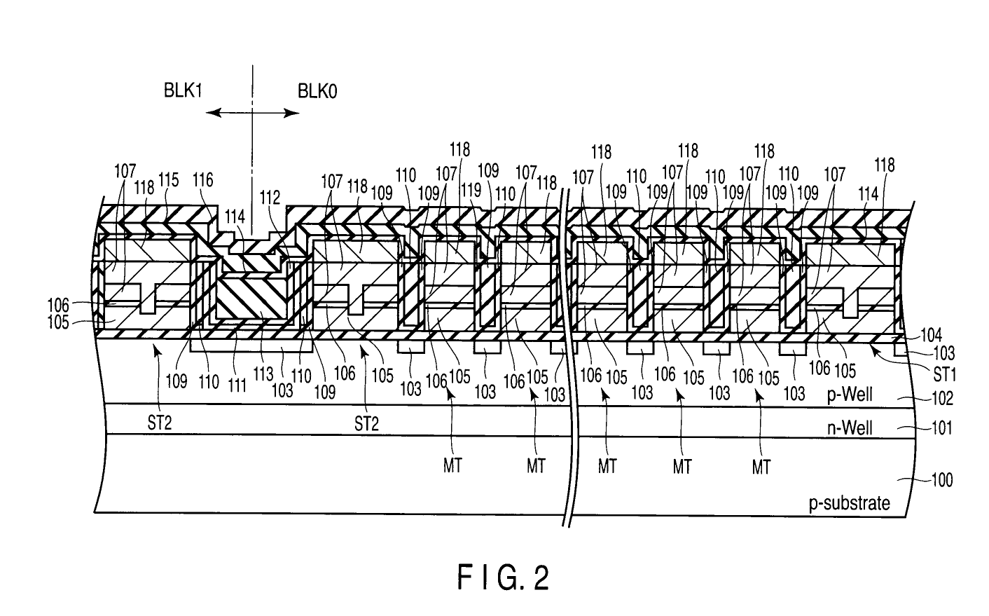

Next, the cross-sectional view of the memory cell array 1 with the above configuration is explained with reference to FIG. 2. FIG. 2 is a cross-sectional view particularly showing block BLK0 and select transistor ST2 of block BLK1 in the memory cell array 1 along the bit line BL direction. As shown in FIG. 2, an n-type well region 101 is formed in the surface area of a p-type semiconductor substrate 100. A p-well region 102 is formed in the surface area of the n-type well region 101. A gate insulating film 104 is formed on the p-well region 102. Gate electrodes of the memory cell transistors MT and the select transistors ST1, ST2 are formed on the gate insulating film 104. The gate electrodes of the memory cell transistors MT and the select transistors ST1, ST2 are formed with the stacked structures each having an FG structure. The stacked structure is formed by sequentially forming a polysilicon layer 105, an inter gate insulating film 106, a polysilicon film 105 and a polysilicon film 107 on the gate insulating film 104. Further, the surface of the polysilicon film 107 is silicified (alloyed). For example, insulating films 109 with the thickness of approximately 9 to 10 nm are formed on the sidewalls of the gate electrodes of the memory cell transistors MT. For example, the insulating film 109 is a silicon oxide film (that may be hereinafter called an HTO film 109) formed by means of a high-temperature oxidation (HTO: a film formation method by use of a low-pressure CVD method at high temperatures) method. An insulating film 110 is formed on the surface of each insulating film 109. The insulating films 110 are formed on the surfaces of the insulating films 109 to fill gaps between the respective gate electrodes of the memory cell transistors MT. For example, the insulating film 110 is a silicon oxide film (that may be simply called a TEOS film) formed by using tetraethoxysilane (TEOS) as a material.

Likewise, insulating films 109 are formed on the sidewalls of the gate electrodes of select transistors ST2 of blocks BLK0 and BLK1 and insulating films 110 with a film thickness of approximately 65 nm are formed on the surfaces of the insulating films 109. For example, an insulating film 111 of, for example, approximately 5 nm is formed on the surfaces of the insulating films 110 and the gate insulating film 104 that lies between select transistors ST2. For example, the insulating film 111 is formed of TEOS. An insulating film 112 is formed on the surface of the insulating film 111. The insulating film 112 is formed on each of sidewalls of the adjacent select transistors ST2 which are opposite in a gate length direction and is formed along the surface of p-type semiconductor substrate 100 in a region between the adjacent select transistors ST2. For example, the insulating film 112 is formed of SiN. Further, an insulating film 113 is formed to fill a gap between select transistors ST2 of blocks BLK0 and BLK1. For example, the insulating film 113 is an insulating film formed by using boron phosphor silicate glass BPSG) as a material. For example, a phospho-silicate glass (PSG) film, boron-silicate glass (BSG) film or none-doped silicate glass (NSG) film may be used other than the BPSG film. For example, an insulating film 114 with a film thickness of approximately several tens of nanometers is formed to coat the select transistors ST1, ST2, memory cell transistors MT and insulating films 109 to 112. In this embodiment, for example, the insulating film 114 is a film formed of SiN. The insulating film 114 may be formed of Al₂O₃. Thus, the insulating film 113 is isolated from the insulating films 109 and 110 formed between the memory cell transistors MT. That is, the insulating films 109 and 110 filled in the gaps between the respective memory cell transistors MT are isolated from the insulating film 113 by coating them with the insulating film 114.

In each of the memory cell transistors MT explained above, the gate insulating film 104 functions as a tunnel insulating film. The polysilicon film 105 functions as a floating gate and the polysilicon film 107 functions as a control gate. Those of the polysilicon films 107 that are adjacent with respect to the word line WL direction intersecting at right angles with the bit line direction in FIG. 1 are commonly connected and function as a control gate electrode (word line WL). The polysilicon films 105 and 107 are hereinafter referred to as a charge storage layer 105 and control gate 107 in some cases, respectively.

In the select transistors ST1, ST2, those of the polysilicon films 105 that are adjacent in the word line WL direction are commonly connected. The polysilicon films 105 functions as the select gate lines SGS, SDS. Only the polysilicon film 105 may function as the select gate line. In this case, the potentials of the polysilicon films 107 of the select transistors ST1, ST2 are set at preset potentials, that is, the polysilicon films are set in a floating state.

In the surface areas of portions of the p-well region 102 each lying between the gate electrodes, n⁺-type impurity diffusion layers 103 are formed. The n⁺-type impurity diffusion layer 103 is commonly used by the two adjacent transistors and functions as a source (S) or drain (D). Further, the region between the adjacent source and drain functions as a channel region used as an electron mobile region. Thus, transistors used as the memory cell transistors MT and select transistors ST1, ST2 are formed of the above gate electrodes, n⁺-type impurity diffusion layers 103 and channel regions.

For example, an inter layer insulating film 115 formed of TEOS is formed to coat the memory cell transistors MT and select transistors ST1, ST2 on the p-type semiconductor substrate 100. On the inter layer insulating film 115, for example, an insulating film 116 formed of SiN is formed. The inter layer insulating film 115 is formed with a film thickness of approximately 50 nm, for example, and the insulating film 116 is formed with a film thickness of approximately 30 nm, for example.

A contact plug CP2 (not shown) that reaches the n⁺-type impurity diffusion layer 103 that is formed between select transistors ST2 respectively formed in the adjacent blocks BLK0 and BLK1 is formed in the p-well 102. Further, contact plug CP2 may be formed in the inter layer insulating film 115 and insulating film 116 and may be electrically connected to the source. In this case, a metal interconnect layer (not shown) that is connected to contact plug CP2 is formed on the surface of the inter layer insulating film 115. The metal interconnect layer acts as part of the source line SL. Further, a contact plug CP3 (not shown) that reaches the n⁺-type impurity diffusion layer (drain) 103 of select transistor ST1 on the drain side is formed in the inter layer insulating film 115 and insulating film 116. Contact plug CP3 is electrically connected to the bit line BL. Gate length means the direction where a sauce, a channel, and drain are located in a line.

<Manufacturing Process of Memory Cell Array 1>

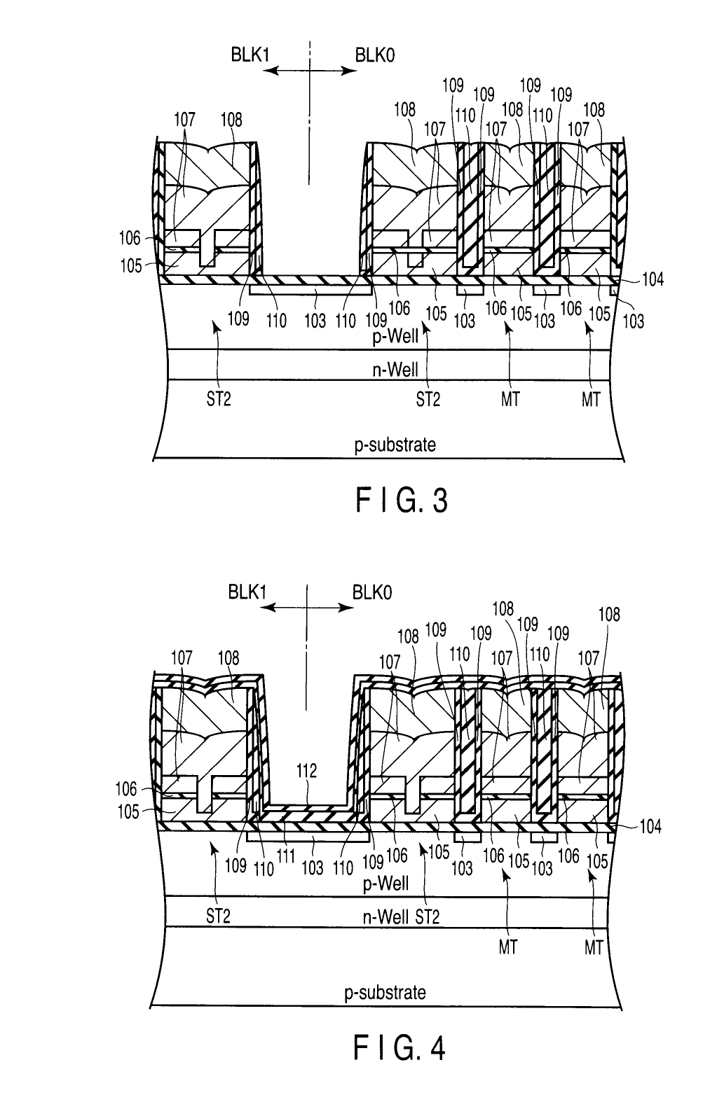

Next, the manufacturing process of the memory cell array 1 is explained with reference to FIGS. 3 to 8. FIGS. 3 to 8 are cross-sectional views sequentially showing the manufacturing steps of the NAND strings 11 shown in FIG. 2 and are cross-sectional views particularly showing select transistor ST2 formed in block BLK1 and select transistor ST2 and memory cell transistors MT formed in block BLK0.

First, as shown in FIG. 3, for example, phosphorus ion is implanted into a p-type semiconductor substrate 100. As a result, an n-type well region 101 is formed. Next, for example, boron ion is implanted into the surface area of the n-type well region 101. Thus, a p-well region 102 is formed in the surface area of the n-type well region 101. Then, a gate oxide film 104 is formed on the p-type semiconductor substrate 100 and an insulating film 105, an inter gate insulating film 106, an insulating film 105, a polysilicon film 107 and a silicon nitride film 108 are sequentially formed on the gate oxide film 104. Subsequently, the silicon nitride film 108, polysilicon film 107 and insulating films 105, 106 are patterned according to the pattern of gate electrodes by use of an anisotropic etching method such as a reactive ion etching (RIE) method. Next, an ion-implantation process is performed to implant impurity into the p-well region 102 with the patterned silicon nitride films 108 used as a mask. As a result, impurity diffusion layers 103 functioning as source and drain regions for the gate electrodes are formed in the surface area of the p-well region 102. Thus, memory cell transistors MT are formed. Further, the select transistors ST1, ST2 are formed by use of a known method. After this, insulating films 109 with a film thickness of approximately 9 to 10 nm are formed on the sidewalls of the memory cell transistors MT and the select transistors ST1, ST2 by use of a high-temperature oxidation (HTO: a film formation method by use of a low-pressure CVD method at high temperatures) method, for example. Further, for example, insulating films 110 with a film thickness of approximately 65 nm are formed on the surfaces of the insulating films 109. As a result, gaps between the memory cell transistors MT are filled with the insulating films 109 and 110.

Next, as shown in FIG. 4, an insulating film 111 with a film thickness of approximately 5 nm, for example, is formed on the silicon nitride films 108 of the memory cell transistors MT and select transistors ST2, on the surface of the insulating film 104 lying between select transistors ST2 and on the insulating films 110. In this case, the insulating film 111 is formed of TEOS used as a material, for example. Then, a SiN film 112 with a film thickness of approximately 20 nm, for example, is formed on the insulating film 111.

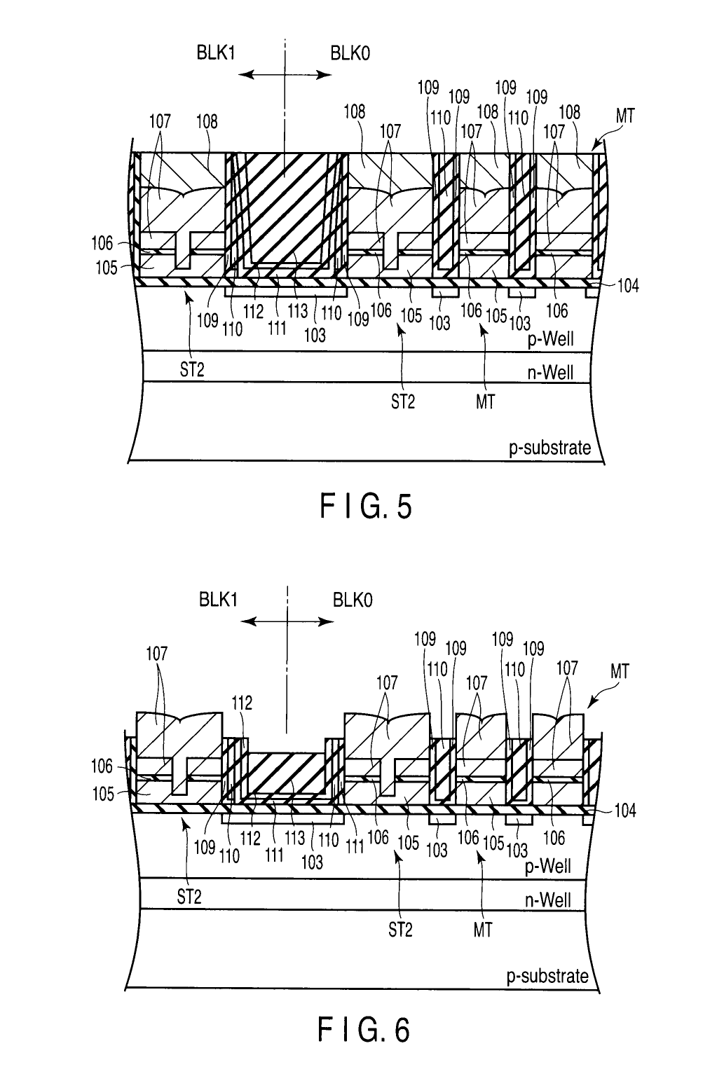

Subsequently, as shown in FIG. 5, a silicon oxide film 113 formed of BPSG used as a material, for example, is formed to fill a gap between select transistors ST2. Then, the silicon nitride films 108, insulating films 109 to 112 and insulating film 113 are made flat by use of a polishing etching method such as a chemical mechanical polishing (CMP) method until the silicon nitride films 108 of select transistors ST2 and memory cell transistors MT are exposed.

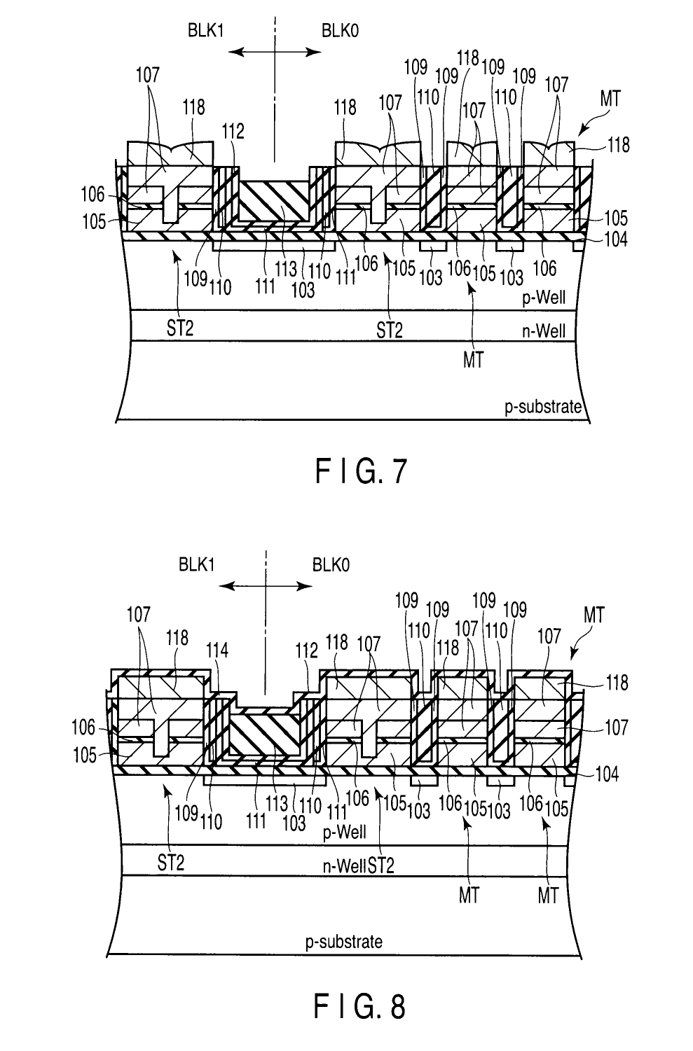

Next, as shown in FIG. 6, an etch-back process is performed to lower the resistances of the polysilicon films 107 functioning as the gate electrodes of the memory cell transistors MT and select transistors ST2. As a result, the upper surfaces of the polysilicon films 107 are exposed. Then, a metal layer such as a Ni layer is formed on the upper surfaces of the polysilicon films 107, insulating films 109 to 112 and insulating film 113 to silicify (alloy) the polysilicon films 107 of the memory cell transistors MT and select transistors ST2. After this, for example, the surfaces of the polysilicon films 107 are silicified to form silicide layers 118 by performing an anneal process at 300° C. to 600° C. in the case of Ni and at 500° C. to 900° C. in the case of Co. The metal layer used for forming the silicide layers may be formed of W other than Ni, Co. Next, for example, only the metal layer such as the Ni layer is separated by wet etching to obtain a device shown in FIG. 7. The silicon nitride films 108 can be silicified not only on the surfaces thereof but also in a FUSI form. Silicidation in the FUSI form is to react a polysilicon film with a refractory metal so as to not only silicify the surface of the polysilicon film but also completely silicify the internal portion of the polysilicon film.

Next, as shown in FIG. 8, a SiN film 114 is formed on the silicide layers 118, polysilicon films 107, insulating films 109 to 112 and insulating film 113. Then, an inter layer insulating film 115 formed of, for example, TEOS used as a material and an insulating film 116 formed of, for example, SiN used as a material are sequentially formed on the SiN film 114. Subsequently, an insulating film is formed on the insulating film 116 and then the device is made flat by means of the CMP method. At this time, the insulating film 116 functions as a stopper. Then, a preset metal interconnect process is performed and the nonvolatile semiconductor memory device shown in FIG. 2 is completed.

### Effect According to Present Embodiment

The reliability of the operation can be enhanced by means of the nonvolatile semiconductor memory device according to this embodiment and the manufacturing method thereof. With the nonvolatile semiconductor memory device according to this embodiment and the manufacturing method thereof, hydrogen atoms can be suppressed from being diffused from the insulating film 113 at the anneal time. Next, a case wherein the SiN film 114 is not formed in this embodiment is explained.

In the manufacturing steps of FIGS. 3 to 8 explained above, the nonvolatile semiconductor memory device is annealed. In this case, if the SiN film 114 is not formed, hydrogen atoms are discharged from the BPSG film 113. The thus discharged hydrogen atoms are trapped by the gate insulating film 104 of the memory cell transistors MT via the inter layer insulating film 115. As a result, an acceptor impurity level is formed on the insulating film 104. In this case, if write voltage is applied to the control gate 107, electrons tunneled via the channel formed in the memory cell transistor MT are trapped by the acceptor level and become difficult to be stored in the charge storage layer 105. The data write state of the memory cell transistor MT is determined according to the number of electrons tunneled via the channel. Even if ‘0’ data (a state in which the threshold voltage is set at higher voltage in the case of a binary value) is temporarily set, electrons that are trapped by the gate insulating film 104 are extracted with time. As a result, charges stored in the charge storage layer 105 appear to become less. That is, it is sometimes determined as ‘1’ data (a state in which the threshold voltage is set at lower voltage in the case of a binary value).

Further, when an insulating film 116 (SiN film) is formed directly on the select transistors ST1, ST2, the memory cell transistors MT and insulating films 109 to 113 instead of the SiN film 114, it can be expected to suppress hydrogen atoms in the insulating film 113 from being diffused due to the presence of the insulating film 116. However, at this time, the following problem occurs. In this case, the insulating film 116 is not formed above the insulating film 114 with the inter layer insulating film 115 interposed therebetween and the insulating film 116 (SiN film) is formed directly on the select transistors ST1, ST2, memory cell transistors MT and insulating films 109 to 113. As described before in the manufacturing process, after the insulating film 116 is formed, an insulating film is formed on the insulating film 116 and then a CMP process is performed with the insulating film 116 used as a stopper. Then, pressure caused by the CMP process is directly applied to the select transistors ST1, ST2 and memory cell transistors MT because the inter layer insulating film 115 is not formed. Therefore, there occurs a possibility that the select transistors ST1, ST2 and memory cell transistors MT may be destroyed.

In this respect, with the nonvolatile semiconductor memory device according to this embodiment and the manufacturing method thereof, the insulating film 114 is formed to coat the BPSG film 113 formed between select transistors ST2, the insulating films 109 to 112, the memory cell transistors MT and the select transistors ST1, ST2. Specifically, the SiN film 114 is formed to isolate the gate insulating film 104 and the insulating films 109, 110 formed between the memory cell transistors MT from the exterior. The SiN film 114 functions as a block film that suppresses passage of hydrogen atoms. Therefore, hydrogen atoms fetched by the BPSG film 113 in the manufacturing process can be suppressed from being discharged to the exterior from the BPSG film 113 at the anneal time. Specifically, hydrogen atoms in the BPSG film 113 can be suppressed from reaching the gate insulating film 104 functioning as a tunnel oxide film of the adjacent memory cell transistor MT. Further, hydrogen atoms diffused from the inter layer insulating film 115 and insulating film 116 formed on the SiN film 114 can be suppressed from reaching the gate insulating film 104. Therefore, the characteristic of the gate oxide film 104 lying directly under the memory cell transistor MT can be enhanced. Further, in the nonvolatile semiconductor memory device according to this embodiment and the manufacturing method thereof, the inter layer insulating film 115 and insulating film 116 are sequentially formed on the SiN film 114. Therefore, even if the CMP process is performed with the insulating film 116 used as a stopper, the inter layer insulating film 115 functions as an absorber and, as a result, a problem that the select transistors ST1, ST2 and memory cell transistors MT are destroyed can be suppressed.

In order to cause the SiN film 114 to function as a block film for suppressing passage of hydrogen atoms with respect to the gate insulating film 104, the SiN film 114 may be formed above the gate insulating film 104. However, as the SiN film is formed above and farther apart from the gate insulating film 104, the effect of the film used as the block film may become more significant.

Further, since diffusion of hydrogen atoms in the BPSG film 113 is also blocked by the insulating film (SiN) 112 that lies below the above film, it is desirable that the insulating film 112 be formed with such a film thickness that can suppress diffusion of hydrogen atoms.

The memory cell transistor MT is not limited to the FG structure or MONOS structure and can be formed with a NOR structure. Further, it can be applied to an EEPROM structure.

The material of the insulating film 114 formed on select transistors ST2, memory cell transistors MT, insulating films 109 to 112 and insulating film 113 is not limited to SiN or Al₂O₃ and various combinations of materials can be made according to the material of the insulating film 113. In other words, the material of the insulating film 114 can be changed according to the material of the insulating film 113. Specifically, if the insulating film 113 is formed of a material other than the material such as BPSG explained in the above embodiment, a material that suppresses atoms diffused from the insulating film 113 from reaching the gate insulating film might be applied to the insulating film 114.

Further, if atoms other than the hydrogen atoms are diffused from the insulating film 113, a material that suppresses the above atoms from being diffused may be applied to the insulating film 114.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A nonvolatile semiconductor memory device comprising:
first gate electrodes each having a charge storage layer formed above a semiconductor substrate with a tunnel insulating film interposed therebetween and a control gate electrode formed above the charge storage layer with an inter gate insulating film interposed therebetween;
a second gate electrode and a third gate electrode formed above the semiconductor substrate with a gate insulating film interposed therebetween, the second and the third gate electrodes are located oppositely in a gate length direction;
a first insulating film formed on each sidewall of the second and the third gate electrodes and formed on the surface of the semiconductor substrate in a region between the second gate electrodes and the third gate electrodes;
a first inter layer insulating film filled in a gap between the second gate electrodes and the third gate electrodes;
a second inter layer insulating film filled in a gap between the first gate electrode which is adjacent to the second gate electrode and the second gate electrode, and gaps between the first gate electrodes; and
a second insulating film formed on the first gate electrodes, the second gate electrode, the third gate electrode, the first insulating film, the first inter layer insulating film, and the second inter layer insulating film to suppress diffusion of hydrogen atoms included in the first inter layer insulating film.

2. The device according to claim 1,
wherein the first inter layer insulating film and the second inter layer insulating film are isolated by the presence of the second insulating film.

3. The device according to claim 1,
wherein the second insulating film is one of a SiN film, an Al₂O₃ film, an AlON film and a multi-layered film having a SiN film, an Al₂O₃ film and a SiN film sequentially formed from the lowest layer.

4. The device according to claim 1, further comprising a third insulating film formed along one of the sidewalls of the second electrodes,
wherein the third insulator film is disposed between the sidewall of the second gate electrode and the first insulator film, and
a distance between the first gate electrode adjacent to the second gate electrode and the second gate electrodes is less than twice the thickness of the third insulating film.

5. The device according to claim 1, further comprising impurity diffusion layers functioning as source and drain regions for the first gate electrodes, and a forth gate electrode formed above the semiconductor substrate with the gate insulating film interposed therebetween,
wherein a plurality of first gate electrodes whose source and drain regions are commonly connected are formed between the second gate electrodes and the forth gate electrode.

6. The device according to claim 1, further comprising a third insulating film formed on the second insulating film and lying directly above at least the first, second and third gate electrodes.

7. The device according to claim 1,
wherein the first insulating film is an SiN film.

8. A nonvolatile semiconductor memory device comprising:
a first memory cell unit including a plurality of first memory cell transistors formed on a semiconductor substrate and each having a stacked gate containing a charge storage layer, and a first select transistor and a second select transistor, the plurality of first memory cell transistors being series-connected between the first select transistor and the second select transistor;
a second memory cell unit including a plurality of second memory cell transistors formed on the semiconductor substrate and each having a stacked gate containing a charge storage layer, and a third select transistor and a fourth select transistor, the plurality of second memory cell transistors being series-connected between the third select transistor and fourth select transistor and the third select transistor commonly using one of source and drain regions with the second select transistor;
a first insulating film formed on sidewalls of the second select transistor and the third select transistor, and on the surface of the semiconductor substrate in a region between the second select transistor and the third select transistor;
a first inter layer insulating film containing hydrogen atoms and filled in a gap between the second select transistor and the third select transistor; and
a second insulating film formed on the first insulating film, the first inter layer insulating film, the second select transistor and the third select transistor to suppress diffusion of the hydrogen atoms.

9. The device according to claim 8, further comprising second inter layer insulating films which are formed to fill gaps between the first memory cell transistor adjacent to the second select transistor and the second select transistor, between every adjacent first memory cell transistors, between the first memory cell transistor adjacent to the first select transistor and the first select transistor, between the second memory cell transistor adjacent to the third select transistor and the third select transistor, between every adjacent second memory cell transistors and between the second memory cell transistor adjacent to the fourth select transistor and the fourth select transistor;
wherein the second insulating film is further formed on the second inter layer insulating films, the first and second memory cell transistors and the first and fourth select transistors to isolate the first inter layer insulating film and second inter layer insulating film.

10. The device according to claim 8,
wherein diffusion of hydrogen atoms in the first inter layer insulating film is suppressed by the presence of the second insulating film.

11. The device according to claim 8,
wherein the second insulating film is one of a SiN film, an Al₂O₃ film, an AlON film and a multi-layered film having a SiN film, an Al₂O₃ film and a SiN film sequentially formed from the lowest layer.

12. The device according to claim 8, further comprising a third insulating film formed along one of the sidewalls of the second select transistor and the third select transistor;
wherein the third insulator film is disposed between the sidewall of the second select transistor and the first insulator film and between the sidewall of the third select transistor and the first insulator film, and
a distance between the first memory cell transistor adjacent to the second select transistor and the second select transistor and a distance between the second memory cell transistor adjacent to the third select transistor and the third select transistor are less than twice the thickness of the third insulating film.

13. The device according to claim 8, further comprising a third insulating film formed on the second insulating film and lying directly above at least the first and second memory cell transistors and the first select transistor to fourth select transistor.

14. The device according to claim 8,
wherein the first insulating film is a SiN film.

15. A manufacturing method of a nonvolatile semiconductor memory device comprising:
forming a first gate electrode having a charge storage layer, a inter gate insulating film and a control gate electrode sequentially formed above a semiconductor substrate with a tunnel insulating film interposed therebetween;
forming a second gate electrode and a third gate electrode above the semiconductor substrate with a gate insulating film interposed therebetween, the second and the third gate electrodes are located oppositely in a gate length direction;
filling a first inter layer insulating film in a gap between the first gate electrode and the second gate electrode;
forming a first insulating film along the surface of the semiconductor substrate and on sidewalls of the second gate electrode and the third gate electrode;
filling a second inter layer insulating film in a gap between the second gate electrode and third gate electrode; and
forming a second insulating film on the first gate electrode, the second gate electrode, the third gate electrode, the first insulating film, the first inter layer insulating film and second inter layer insulating film to suppress diffusion of hydrogen atoms included in the second inter layer insulating film.

16. The method according to claim 15,
wherein the first inter layer insulating film and second inter layer insulating film are isolated by the forming the second insulating film.

17. The method according to claim 15,
wherein the second insulating film is one of a SiN film, an Al₂O₃ film, an AlON film and a multi-layered film having a SiN film, an Al₂O₃ film and a SiN film sequentially formed from the lowest layer.

18. The method according to claim 15, further comprising forming a third insulating film along one of the sidewalls of the second electrode,
wherein the third insulator film is disposed between the one of the second gate electrodes and the first insulator film, and
the first gate electrode and second gate electrode are formed to set a distance between the first gate electrode and second gate electrode less than twice the thickness of the third insulating film.

19. The method according to claim 15, further comprising forming a fourth gate electrode having a charge storage layer, a inter gate insulating film and a control gate electrode sequentially formed above a semiconductor substrate with a tunnel insulating film interposed therebetween and being adjacent to the first gate electrode;
forming a fifth gate electrode formed above the semiconductor substrate with a gate insulating film interposed therebetween; and
forming impurity diffusion layers functioning as source and drain regions of the first gate electrode,
wherein the second gate electrode and the fifth gate electrode are formed to sandwich the first gate electrode and fourth gate electrode whose source and drain regions are commonly connected.

20. The method according to claim 15, further comprising forming a third insulating film on the second insulating film in portions directly above at least the first gate electrode, second gate electrode, third gate electrodes, fourth gate electrode and fifth electrode.
